(19) United States
(12) Patent Application Publication
(10) Pub. No.: US 2025/0081468 A1
(43) Pub. Date: Mar. 6, 2025

(54) SEMICONDUCTOR MEMORY DEVICE

(71) Applicant: Samsung Electronics Co., Ltd., Suwon-si (KR)

(72) Inventors: Chang Min CHOI, Suwon-si (KR); Chang Heon LEE, Suwon-si (KR); Ju Seong MIN, Suwon-si (KR); Taek Kyu YOON, Suwon-si (KR)

(73) Assignee: Samsung Electronics Co., Ltd., Suwon-si (KR)

(21) Appl. No.: 18/821,055

(22) Filed: Aug. 30, 2024

(30) Foreign Application Priority Data
Sep. 1, 2023 (KR) 10-2023-0116171

(51) Int. Cl. H10B 43/40; G11C 5/06; G11C 16/04; H10B 43/10; H10B 43/27; H10B 43/35

(52) U.S. Cl. CPC H10B 43/40; G11C 5/063; G11C 16/0483; H10B 43/10; H10B 43/27; H10B 43/35

(57) ABSTRACT

Provided a semiconductor memory device. The semiconductor memory device comprises a cell structure, and a peripheral circuit structure electrically connected to the cell structure. The cell structure includes a plurality of gate electrodes stacked in a vertical direction and spaced apart from each other in the vertical direction, a channel structure penetrating the plurality of gate electrodes in the vertical direction, and a bit-line connected to the channel structure. The peripheral circuit structure includes an active area, a gate structure on the active area, the gate structure intersecting the active area, a source/drain area on at least one side of the gate structure and in the active area, an insulating spacer covering the gate structure, a conductive spacer on a sidewall of the insulating spacer and electrically connected to the source/drain area, and a contact electrically connected to the conductive spacer. At least a portion of a topmost surface of the insulating spacer is coplanar with at least a portion of a topmost surface of the conductive spacer.

### CROSS-REFERENCE TO RELATED APPLICATION

This application claims priority from Korean Patent Application No. 10-2023-0116171 filed on Sep. 1, 2023 in the Korean Intellectual Property Office, and all the benefits accruing therefrom under 35 U.S.C. 119, the contents of which in its entirety are herein incorporated by reference.

### BACKGROUND

The present disclosure relates to a semiconductor memory device.

In order to meet high performance and low price of a semiconductor memory device as demanded by consumers, it is required to increase integration of the semiconductor memory device. The integration of the semiconductor memory devices is an important factor in determining a price thereof. Thus, the semiconductor memory device having increased integration is particularly required.

In a structure of a transistor that controls the operation of a memory cell, research is underway on a process for implementing one or more transistors with different gate insulating film thicknesses on one active area.

### SUMMARY

At least one embodiment relates to a semiconductor memory device with improved integration.

The technical purposes for implementing the inventive concepts disclosed herein are not limited to the above-mentioned technical purpose. Other technical purposes and advantages that are not mentioned may be understood based on following descriptions, and may be more clearly understood based on various example embodiments. Further, it will be easily understood that the technical purposes and advantages according to various example embodiments may be realized using means illustrated in the claims and combinations thereof.

According to various example embodiments, there is provided a semiconductor memory device comprising a cell structure, and a peripheral circuit structure electrically connected to the cell structure. The cell structure includes a plurality of gate electrodes stacked in a vertical direction and spaced apart from each other in the vertical direction, a channel structure penetrating the plurality of gate electrodes in the vertical direction, and a bit-line connected to the channel structure. The peripheral circuit structure includes an active area, a gate structure on the active area, the gate structure intersecting the active area, a source/drain area on at least one side of the gate structure and in the active area, an insulating spacer covering the gate structure, a conductive spacer on a sidewall of the insulating spacer and electrically connected to the source/drain area, and a contact electrically connected to the conductive spacer. At least a portion of a topmost surface of the insulating spacer is coplanar with at least a portion of a topmost surface of the conductive spacer.

According to various example embodiments, there is provided a semiconductor memory device comprising a cell structure; and a peripheral circuit structure electrically connected to the cell structure. The cell structure includes a plurality of gate electrodes stacked in a vertical direction and spaced apart from each other in the vertical direction, a channel structure penetrating the plurality of gate electrodes in the vertical direction, and a bit-line connected to the channel structure. The peripheral circuit structure includes an active area extending in a first direction, a gate structure on the active and extending in a second direction, wherein the gate structure intersects the active area, a source/drain area on at least one side of the gate structure and in the active area, an insulating spacer covering an upper surface and a sidewall of the gate structure and including an insulating material, and a spacer structure surrounding a sidewall of the insulating spacer. The spacer structure includes a semiconductor spacer including a semiconductor material, a conductive spacer including a conductive material and electrically connected to the source/drain area, and a contact electrically connected to the conductive spacer. The gate structure includes a pair of first sidewalls extending in the first direction and a pair of second sidewalls extending in the second direction. In a plan view of the semiconductor memory device, the conductive spacer is on the pair of second sidewalls and is absent on the pair of first sidewalls.

According to various example embodiments, there is provided a semiconductor memory device comprising a cell structure; and a peripheral circuit structure electrically connected to the cell structure. The cell structure includes a plurality of gate electrodes stacked in a vertical direction and spaced apart from each other in the vertical direction, a channel structure penetrating the plurality of gate electrodes in the vertical direction, and a bit-line connected to the channel structure. The peripheral circuit structure includes an active area extending in a first direction, a gate structure on the active area and extending in a second direction, wherein the gate structure intersects the active area, and the gate structure includes a pair of first sidewalls extending in the first direction and a pair of second sidewalls extending in the second direction, a source/drain area on each of the pair of second sidewalls of the gate structure and in the active area, an insulating spacer covering an upper surface of the gate structure, the pair of first sidewalls, and the pair of second sidewalls, and including an insulating material, a spacer structure surrounding an outer sidewall of the insulating spacer, wherein the spacer structure includes a semiconductor spacer including a semiconductor material, a conductive spacer including a conductive material and electrically connected to the source/drain area, an etch stop film covering a portion of the insulating spacer, the semiconductor spacer, and a portion of the source/drain area, and a contact electrically connected to the conductive spacer. The etch stop film does not overlap the conductive spacer in the vertical direction. The conductive spacer overlaps the pair of second sidewalls in the first direction, and does not overlap the pair of first sidewalls in the second direction. A topmost surface of the spacer structure is coplanar with an upper surface of the insulating spacer.

### BRIEF DESCRIPTION OF DRAWINGS

The above and other aspects and features of various example embodiments will become more apparent by describing in detail embodiments thereof with reference to the attached drawings, in which:

FIG. 1 is an illustrative block diagram for illustrating a semiconductor memory device according to various example embodiments.

FIG. 2 is an illustrative circuit diagram for illustrating a semiconductor memory device according to various example embodiments.

FIG. 3 is an illustrative cross-sectional view of a semiconductor memory device according to various example embodiments.

FIG. 4 is an enlarged view of an R area in FIG. 3.

FIG. 5 is a plan view for illustrating a peripheral circuit structure of a semiconductor memory device according to various example embodiments.

FIG. 6 is a cross-sectional view cut along a line A-A′ in FIG. 5.

FIG. 7 is a cross-sectional view cut along a line B1-B1′ in FIG. 5.

FIGS. 8 to 18 are diagrams of semiconductor memory devices according to some further embodiments.

FIGS. 19 to 26 are diagrams of intermediate structures corresponding to intermediate steps of the method for the manufacturing the semiconductor memory device according to various example embodiments of the present disclosure.

FIG. 27 is an illustrative block diagram for illustrating an electronic system according to various example embodiments.

FIG. 28 is an illustrative perspective view for illustrating an electronic system according to various example embodiments.

FIG. 29 is a schematic cross-sectional view taken along a line I-I′ of FIG. 28.

### DETAILED DESCRIPTIONS

The terms “first”, “second”, and the like as used herein are used to describe various elements or components, but these elements or components are not limited by these terms. These terms are used only in order to distinguish one element or component from another element or component. Accordingly, a first element or component mentioned below may also be a second element or component within the technical spirit of the present disclosure.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Hereinafter, embodiments of the present disclosure will be described in detail with reference to the accompanying drawings. The same reference numerals are used for the same components in the drawings, and duplicate descriptions thereof are omitted.

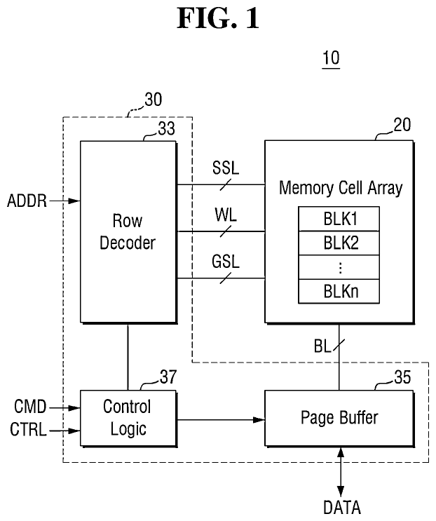

FIG. 1 is an illustrative block diagram for illustrating a semiconductor memory device according to some embodiments.

Referring to FIG. 1, a semiconductor memory device 10 according to some embodiments includes a memory cell array 20 and a peripheral circuit 30.

The memory cell array 20 may include a plurality of memory cell blocks (BLK1 to BLKn). Each of the memory cell blocks BLK1 to BLKn may include a plurality of memory cells. The memory cell array 20 may be connected to the peripheral circuit 30 via a bit-line BL, a word-line WL, at least one string select line SSL, and at least one ground select line GSL. Specifically, the memory cell blocks BLK1 to BLKn may be connected to a row decoder 33 via the word-line WL, the string select line SSL, and the ground select line GSL. Further, the memory cell blocks BLK1 to BLKn may be connected to a page buffer 35 via the bit-line BL.

The peripheral circuit 30 may receive an address ADDR, a command CMD, and a control signal CTRL from an external device to the semiconductor memory device 10 and may transmit and receive data DATA to and from an external device to the semiconductor memory device 10. The peripheral circuit 30 may include a control logic 37, the row decoder 33, and the page buffer 35. Although not shown, the peripheral circuit 30 may further include various sub-circuits such as an input/output circuit, a voltage generation circuit for generating various voltages required for an operation of the semiconductor memory device 10, and an error correction circuit for correcting an error of the data DATA read from the memory cell array 20.

The control logic 37 may be connected to the row decoder 33, the input/output circuit, and the voltage generation circuit. The control logic 37 may control overall operations of the semiconductor memory device 10. The control logic 37 may generate various internal control signals used in the semiconductor memory device 10 in response to the control signal CTRL. For example, the control logic 37 may adjust a voltage level of a voltage supplied to the word-line WL and the bit-line BL when performing a memory operation such as a program operation or an erase operation.

The row decoder 33 may select at least one from the plurality of memory cell blocks BLK1 to BLKn in response to the address ADDR, and may select at least one word-line WL, at least one string select line SSL, and at least one ground select line GSL of the selected at least one memory cell block BLK1 to BLKn. Further, the row decoder 33 may transmit a voltage for performing a memory operation to the word-line WL of the selected at least one memory cell block BLK1 to BLKn.

The page buffer 35 may be connected to the memory cell array 20 via the bit-line BL. The page buffer 35 may operate as a writer driver or a sense amplifier. Specifically, when performing a program operation, the page buffer 35 operates as the writer driver to apply a voltage based on the data DATA to be stored in the memory cell array 20 to the bit-line BL. On the other hand, when performing a read operation, the page buffer 35 may operate as the sense amplifier to detect the data DATA stored in the memory cell array 20.

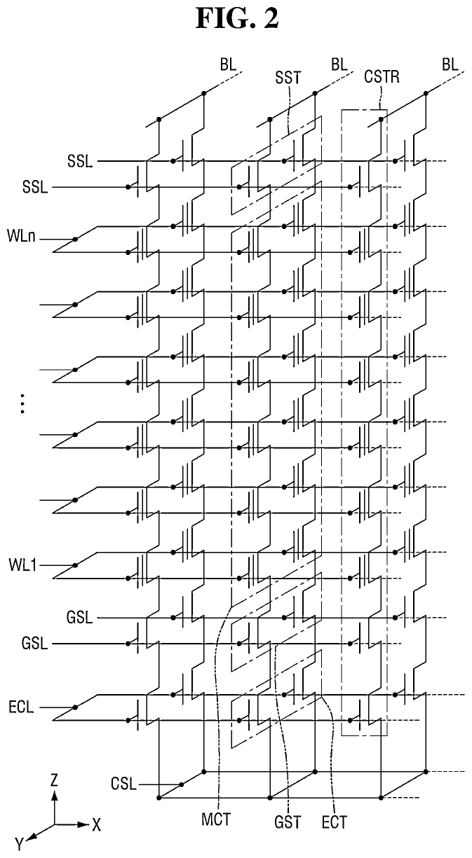

FIG. 2 is an illustrative circuit diagram for illustrating a semiconductor memory device according to some embodiments.

Referring to FIG. 2, a memory cell array (e.g., 20 in FIG. 1) of a semiconductor memory device according to some embodiments includes a common source line CSL, a plurality of bit-lines BL, and a plurality of cell strings CSTR.

The common source line CSL may extend in a x direction X. In some example embodiments, a plurality of common source lines CSL may be arranged in a two-dimensional manner. For example, the plurality of common source lines CSL may be spaced apart from each other and extend in the x direction X. The same voltage may be applied to the common source lines CSL. Alternatively, different voltages may be individually applied to be the common source lines CSL.

The plurality of bit-lines BL may be arranged in a two-dimensional manner. For example, the bit-lines BL may be spaced apart from each other and extend in a y direction Y intersecting the x direction X. The plurality of cell strings CSTR may be connected in parallel to each of the bit-lines BL. The cell strings CSTR may be connected to the common source line CSL. That is, the plurality of cell strings CSTR may be disposed between the bit-lines BL and the common source line CSL.

Each of the cell strings CSTR may include a ground select transistor GST connected to the common source line CSL, a string select transistor SST connected to the bit-line BL, and a plurality of memory cell transistors MCT disposed between the ground select transistor GST and the string select transistor SST. Each of the memory cell transistors MCT may include a data storage element. The ground select transistor GST, the string select transistor SST and the memory cell transistors MCT may be connected in series to each other in a z direction Z. As used herein, the x direction X, the y direction Y, and the z direction Z may be substantially perpendicular to each other.

The common source line CSL may be commonly connected to sources of the ground select transistors GST. Further, a ground select line GSL, a plurality of word-lines WL1 to WLn and a string select line SSL may be disposed between the common source line CSL and the bit-line BL. The ground select line GSL may act as a gate electrode of the ground select transistor GST. The word-lines WL1 to WLn may be respectively used as gate electrodes of the memory cell transistors MCT. The string select line SSL may act as a gate electrode of the string select transistor SST.

In some example embodiments, an erase control transistor ECT may be disposed between the common source line CSL and the ground select transistor GST. The common source line CSL may be commonly connected to sources of the erase control transistors ECT. Further, an erase control line ECL may be disposed between the common source line CSL and the ground select line GSL. The erase control line ECL may act as a gate electrode of the erase control transistor ECT. The erase control transistors ECT may generate gate induced drain leakage (GIDL) to execute an erase operation of the memory cell array.

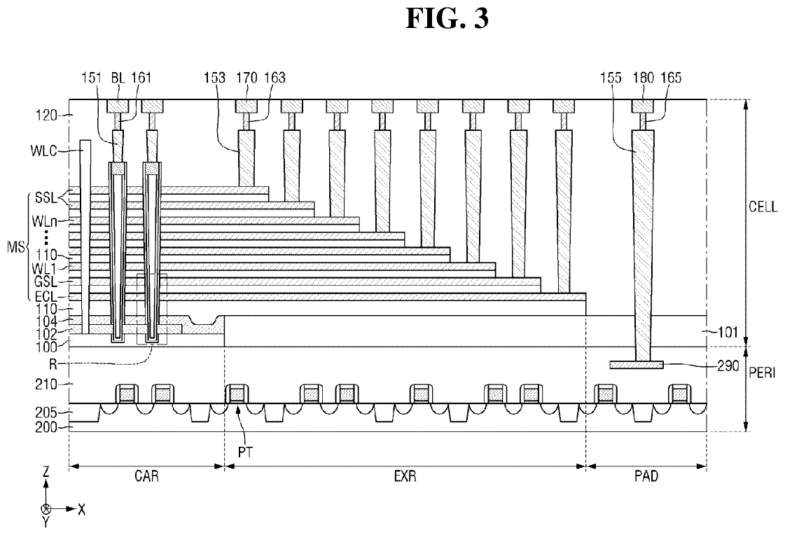

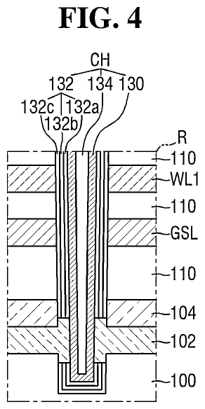

FIG. 3 is an illustrative cross-sectional view of a semiconductor memory device according to some embodiments. FIG. 4 is an enlarged view of an R area in FIG. 3.

Referring to FIG. 3 and FIG. 4, the semiconductor memory device according to some embodiments includes a cell structure CELL and a peripheral circuit structure PERI.

In some example embodiments, the cell structure CELL includes a cell substrate 100, a mold structure MS, a cell interlayer insulating film 120, a channel structure CH, a word-line cutting structure WLC, a bit-line BL, a plurality of cell contacts 153, and a through-contact 155.

The semiconductor memory device according to some embodiments may include a cell array area CAR, an extension area EXR, and a pad area PAD. Although the cell array area CAR, the extension area EXR, and the pad area PAD are illustrated as being connected to each other, the technical idea of various example embodiments are not limited thereto.

A memory cell array including a plurality of memory cells (e.g., 20 in FIG. 1) may be formed in the cell array area CAR. For example, the channel structure CH, the bit-line BL and gate electrodes ECL, GSL, WL1 to WLn, and SSL, etc. as described later may be disposed in the cell array area CAR.

The extension area EXR may be disposed around the cell array area CAR. In the extension area EXR, the gate electrodes ECL, GSL, WL1 to WLn, and SSL as described later may be stacked in a stepwise manner. Further, in the extension area EXR, the plurality of cell contacts 153, etc. as described below may be disposed.

The pad area PAD may be disposed inwardly of the cell array area CAR and the extension area EXR or may be disposed outwardly of the cell array area CAR and the extension area EXR. In the pad area PAD, the through-contact 155 or the like to be described later may be disposed.

A substrate may include the cell array area CAR, the extension area EXR, and the pad area PAD. The substrate may include the cell substrate 100 and an insulating pattern 101. However, various example embodiments are not limited thereto.

The cell substrate 100 may include, for example, a semiconductor substrate such as a silicon substrate, a germanium substrate, or a silicon-germanium substrate. Alternatively, the cell substrate 100 may include a silicon-on-insulator (SOI) substrate or a germanium-on-insulator (GOI) substrate. In some example embodiments, the cell substrate 100 may contain impurities. For example, the cell substrate 100 may contain n-type impurities such as phosphorus (P), arsenic (As), and the like.

The insulating pattern 101 may be disposed in the extension area EXR and the pad area PAD. The insulating pattern 101 may include, for example, at least one of silicon oxide, silicon nitride, silicon oxynitride, or silicon carbide. However, various example embodiments are not limited thereto. Unlike what is illustrated, the insulating pattern 101 may be disposed in the cell substrate 100.

The mold structure MS may be disposed on a front surface (for example, an upper surface) of the cell substrate 100. The mold structure MS may include the plurality of gate electrodes ECL, GSL, WL1 to WLn, and SSL, and a plurality of mold insulating films 110 that are alternately stacked on top of each other while being disposed on the cell substrate 100. Each of the gate electrodes ECL, GSL, WL1 to WLn, and SSL and each of the mold insulating films 110 may have a layered structure extending in a parallel manner with the upper surface of the cell substrate 100. The gate electrodes ECL, GSL, WL1 to WLn, and SSL may be sequentially stacked on the cell substrate 100 while being spaced apart from each other via each of the mold insulating films 110.

The gate electrodes ECL, GSL, WL1 to WLn, and SSL may be stacked in a stepwise manner in the extension area EXR. For example, the gate electrodes ECL, GSL, WL1 to WLn, and SSL may extend so as to have different lengths in the x direction X and thus may be stacked in the stepwise manner. In some example embodiments, the gate electrodes ECL, GSL, WL1 to WLn, and SSL may extend so as to have different lengths in the y direction Y and thus may be stacked in the stepwise manner. Accordingly, a portion of each of the gate electrodes ECL, GSL, WL1 to WLn, and SSL may not be covered with other gate electrodes so as to be exposed. The exposed portion of each of the gate electrodes ECL, GSL, WL1 to WLn, and SSL may contact each of the plurality of cell contacts 153.

In some example embodiments, the gate electrodes ECL, GSL, WL1 to WLn, and SSL may include the erase control line ECL, the ground select line GSL, and the plurality of word-lines WL1 to WLn sequentially stacked on the cell substrate 100. In some further embodiments, the erase control line ECL may be omitted.

The mold insulating films 110 may be stacked in a stepped manner in the extension area EXR. For example, the mold insulating films 110 may extend so as to have different lengths in the x direction X and thus may be stacked in the stepped manner. In some example embodiments, the mold insulating films 110 may extend so as to have different lengths in the y direction Y and thus may be stacked in the stepped manner.

Each of the gate electrodes ECL, GSL, WL1 to WLn, and SSL may include a conductive material, for example, a metal such as tungsten (W), cobalt (Co), or nickel (Ni), or a semiconductor material such as silicon. However, various example embodiments are not limited thereto. In one example, each of the gate electrodes ECL, GSL, WL1 to WLn, and SSL may include tungsten (W). Unlike what is illustrated, each of the gate electrodes ECL, GSL, WL1 to WLn, and SSL may have a multi-layer structure. For example, when each of the gate electrodes ECL, GSL, WL1 to WLn, and SSL has the multi-layer structure, each of the gate electrodes ECL, GSL, WL1 to WLn, and SSL may include a gate electrode barrier film and a gate electrode filling film. The gate electrode barrier film may include, for example, titanium nitride (TiN), and the gate electrode filling film may include tungsten (W). However, various example embodiments are not limited thereto.

The mold insulating film 110 may include an insulating material, for example, at least one of silicon oxide, silicon nitride, or silicon oxynitride. However, various example embodiments are not limited thereto. In one example, the mold insulating film 110 may include silicon oxide.

The channel structure CH may be disposed in the mold structure MS and in the cell array area CAR. The channel structure CH may extend in a vertical direction (hereinafter referred to as the z direction Z) intersecting the upper surface of the cell substrate 100 and may extend through the mold structure MS and the gate electrodes ECL, GSL, WL1 to WLn, and SSL. For example, the channel structure CH may have a pillar shape (e.g., a cylinder shape) extending in the z direction Z. Accordingly, the channel structure CH may intersect each of the gate electrodes ECL, GSL, WL1 to WLn, and SSL.

The channel structure CH may include a semiconductor pattern 130 and an information storage film 132.

The semiconductor pattern 130 may extend in the z direction Z and extend through the mold structure MS. Although the semiconductor pattern 130 is shown only as having a shape of a cup, this is only illustrative. For example, the semiconductor pattern 130 may have various shapes such as a cylindrical shape, a square column shape, and a solid pillar shape. The semiconductor pattern 130 may include, for example, a semiconductor material such as monocrystalline silicon, polycrystalline silicon, an organic semiconductor material, or a carbon nanostructure, etc. However, various example embodiments are not limited thereto.

The information storage film 132 may be interposed between the semiconductor pattern 130 and each of the gate electrodes ECL, GSL, WL1 to WLn, and SSL. For example, the information storage film 132 may extend along an outer surface of the semiconductor pattern 130. The information storage film 132 may include, for example, at least one of silicon oxide, silicon nitride, silicon oxynitride, or a high dielectric constant (high-k) material having a higher dielectric constant than that of silicon oxide. The high dielectric constant (high-k) material may include, for example, at least one of aluminum oxide, hafnium oxide, lanthanum oxide, tantalum oxide, titanium oxide, lanthanum hafnium oxide, lanthanum aluminum oxide, dysprosium scandium oxide, or combinations thereof. However, example embodiments are not limited thereto.

In some example embodiments, the information storage film 132 may be formed as a stack of multiple films. For example, as shown in FIG. 4, the information storage film 132 may include a tunnel insulating film 132a, a charge storage film 132b, and a blocking insulating film 132c sequentially stacked on the outer surface of the semiconductor pattern 130.

The tunnel insulating film 132a may include, for example, silicon oxide or a high-k material having a higher dielectric constant than that of silicon oxide, such as aluminum oxide (Al₂O₃) or hafnium oxide (HfO₂). The charge storage film 132b may include, for example, silicon nitride. The blocking insulating film 132c may include, for example, silicon oxide or a high-k material having a higher dielectric constant than that of silicon oxide, such as aluminum oxide (Al₂O₃) or hafnium oxide (HfO₂).

In some example embodiments, the channel structure CH may further include a filling pattern 134. The filling pattern 134 may be formed to fill an inner space defined by the cup-shaped semiconductor pattern 130. The filling pattern 134 may include an insulating material, for example, silicon oxide. However, various example embodiments are not limited thereto.

In some example embodiments, the channel structure CH may further include a channel pad 136. The channel pad 136 may be formed to be connected to the semiconductor pattern 130. For example, the channel pad 136 may be formed in the cell interlayer insulating film 120 to be described later and may be connected to a top of the semiconductor pattern 130. The channel pad 136 may include, for example, polysilicon doped with impurities. However, various example embodiments are not limited thereto.

In some example embodiments, a source layer 102 and a source support layer 104 may be sequentially formed on the cell substrate 100. The source layer 102 and the source support layer 104 may be interposed between the cell substrate 100 and the mold structure MS. For example, the source layer 102 and the source support layer 104 may extend along the upper surface of the cell substrate 100.

In some example embodiments, the source layer 102 may be formed to be connected to the semiconductor pattern 130 of the channel structure CH. For example, as shown in FIG. 4, the source layer 102 may extend through the information storage film 132 and contact the semiconductor pattern 130. The source layer 102 may be provided as a common source line (e.g., CSL in FIG. 2) of the semiconductor memory device. The source layer 102 may include, for example, impurity-doped polysilicon or a metal. However, various example embodiments are not limited thereto.

In some example embodiments, the channel structure CH may extend through the source layer 102 and the source support layer 104. For example, a bottom of the channel structure CH may extend through the source layer 102 and the source support layer 104 and be buried in the cell substrate 100.

In some example embodiments, the source support layer 104 may be used as a support layer to prevent the mold stack from collapsing in a replacement process for forming the source layer 102.

Although not shown, a base insulating film may be interposed between the cell substrate 100 and the source layer 102. The base insulating film may include, for example, at least one of silicon oxide, silicon nitride, and silicon oxynitride. However, various example embodiments are not limited thereto.

In some example embodiments, the insulating pattern 101 may be formed in the extension area EXR and the pad area PAD. It is illustrated that an upper surface of the insulating pattern 101 is coplanar with an upper surface of the source support layer 104. However, this is only illustrative. In another example, a vertical level of the upper surface of the insulating pattern 101 may be higher than that of the upper surface of the source support layer 104.

The word-line cutting structure WLC may cut the mold structure MS. The mold structure MS may be cut by the word-line cutting structure WLC so as to be divided into portions respectively constituting a plurality of memory cell blocks (e.g., BLK1 to BLKn in FIG. 1). For example, although not shown, two adjacent word-line cutting structures WLC may define one memory cell block therebetween. A plurality of channel structures CH may be disposed in each of the memory cell blocks defined by the word-line cutting structures WLC.

In some example embodiments, the word-line cutting structure WLC may cut the source layer 102 and the source support layer 104. The lower surface of the word-line cutting structure WLC is illustrated to be only coplanar with a lower surface of the source layer 102. However, this is only illustrative. In another example, a vertical level of the lower surface of the word-line cutting structure WLC may be lower than that of the lower surface of the source layer 102.

In some example embodiments, the word-line cutting structure WLC may include an insulating material. For example, the insulating material may fill the word-line cutting structure WLC. The insulating material may include, for example, at least one of silicon oxide, silicon nitride, or silicon oxynitride. However, various example embodiments are not limited thereto.

Although not shown, a string isolation structure may be disposed in the mold structure MS. The string isolation structure may cut the string select line SSL. The string isolation structure may divide each of the memory cell blocks defined by the word-line cutting structures WLC into portions respectively constituting a plurality of string areas. For example, the string isolation structure may define two string areas in one memory cell block.

The cell interlayer insulating film 120 may be disposed on the mold structure MS. The cell interlayer insulating film 120 may cover the plurality of channel structures CH, the plurality of cell contacts 153, and the through-contact 155. The cell interlayer insulating film 120 may include an oxide-based insulating material. The cell interlayer insulating film 120 may include, for example, at least one of silicon oxide, silicon oxynitride, or a low-k material with a lower dielectric constant than that of silicon oxide. However, various example embodiments are not limited thereto.

The bit-line BL may be disposed on the substrate and in the cell array area CAR. The bit-line BL may be formed on the mold structure MS. The bit-line BL may be the bit-line (BL in FIG. 2) of the semiconductor memory device. The bit-line BL may be disposed in the cell interlayer insulating film 120. The bit-line BL may extend in the y direction Y.

Further, the bit-line BL may be connected to the plurality of channel structures CH. For example, first and second bit-line contacts 151 and 161 connected to a top of each of the channel structures CH may be formed in the cell interlayer insulating film 120 The first bit-line contact 151 is disposed on the channel structure CH. The first bit-line contact 151 may be connected to the channel pad 136. The second bit-line contact 161 is disposed on the first bit-line contact 151. The second bit-line contact 161 may be connected to the bit-line BL. The second bit-line contact 161 may be disposed between the bit-line BL and the first bit-line contact 151. The bit-line BL may be electrically connected to the channel structures CH via the first and second bit-line contacts 151 and 161.

The bit-line BL may include a conductive material. For example, the bit-line BL may include tungsten (W) or copper (Cu). However, various example embodiments are not limited thereto.

The plurality of cell contacts 153 may be disposed on the substrate and in the extension area EXR. The plurality of cell contacts 153 may be disposed in the extension area EXR and may extend in the z direction Z and may extend through the cell interlayer insulating film 120. Each of the plurality of cell contacts 153 may be connected to one of the plurality of gate electrodes ECL, GSL, WL1 to WLn, and SSL. For example, each of the plurality of cell contacts 153 may land on the topmost gate electrode among the plurality of gate electrodes ECL, GSL, WL1 to WLn, and SSL. That is, each of the plurality of cell contacts 153 may be electrically connected to the topmost gate electrode among the plurality of gate electrodes ECL, GSL, WL1 to WLn, and SSL.

All of upper surfaces of the plurality of cell contacts 153 may be coplanar with each other. Further, all of lower surfaces of the plurality of cell contacts 153 may be coplanar with each other. However, the technical idea of various example embodiments are not limited thereto.

A plurality of first metal patterns 170 may be disposed on the substrate and in the extension area EXR. The plurality of first metal patterns 170 may be disposed on the mold structure MS. Further, the plurality of first metal patterns 170 may be respectively connected to the plurality of cell contacts 153. For example, a first via contact 163 may be formed between each of the plurality of first metal patterns 170 and each of the cell contacts 153. Each of the plurality of first metal patterns 170 and each of the cell contacts 153 may be electrically connected to each other via each first via contact 163.

Each of the plurality of first metal patterns 170 may include a conductive material. For example, each of the plurality of first metal patterns 170 may include tungsten (W) or copper (Cu). However, various example embodiments are not limited thereto.

The through-contact 155 may be disposed on the substrate and in the pad area PAD. The through-contact 155 may be disposed in the pad area PAD and may extend in the z direction Z and may extend through the cell interlayer insulating film 120. Further, the through-contact 155 may extend through the insulating pattern 101. The through-contact 155 may extend through the insulating pattern 101 and then be connected to a peripheral circuit element PT of the peripheral circuit structure PERI, which will be described later. For example, the through-contact 155 may be connected to a wiring pattern 290 of the peripheral circuit structure PERI.

A plurality of second metal patterns 180 may be disposed on the substrate and in the pad area PAD. The plurality of second metal patterns 180 may be disposed in the cell interlayer insulating film 120. The plurality of second metal patterns 180 may be connected to the through-contact 155. For example, a second via contact 165 may be formed between some of the plurality of second metal patterns 180 and the through-contact 155. Some of the plurality of second metal patterns 180 and the through-contact 155 may be electrically connected to each other via the second via contact 165.

Each of the plurality of second metal patterns 180 may include a conductive material. For example, each of the plurality of second metal patterns 180 may include tungsten (W) or copper (Cu). However, various example embodiments are not limited thereto.

In some example embodiments, the peripheral circuit structure PERI may include a peripheral circuit substrate 200 and the peripheral circuit element PT.

The peripheral circuit substrate 200 may be disposed under the cell substrate 100. For example, an upper surface of the peripheral circuit substrate 200 may face the lower surface of the cell substrate 100. The peripheral circuit substrate 200 may include, for example, a semiconductor substrate such as a silicon substrate, a germanium substrate, or a silicon-germanium substrate. Alternatively, the peripheral circuit substrate 200 may be embodied as a silicon-on-insulator (SOI) substrate or a germanium-on-insulator (GOI) substrate etc.

The peripheral circuit element PT may be formed on the peripheral circuit substrate 200. The peripheral circuit element PT may constitute a peripheral circuit (e.g., 30 in FIG. 1) that controls the operation of the semiconductor memory device. For example, the peripheral circuit clement PT may include a control logic (e.g., 37 in FIG. 1), a row decoder (e.g., 33 in FIG. 1), a page buffer (e.g., 35 in FIG. 1), etc. In one example, the peripheral circuit element PT may be a page buffer and may control the operation of the bit line BL. However, the technical idea of various example embodiments are not limited thereto.

In the following descriptions, a surface of the peripheral circuit substrate 200 on which the peripheral circuit clement PT is disposed may be referred to as a front surface of the peripheral circuit substrate 200. Conversely, a surface of the peripheral circuit substrate 200 opposite to the front surface of the peripheral circuit substrate 200 may be referred to as a back surface or a rear surface of the peripheral circuit substrate 200.

The peripheral circuit element PT may include, for example, a transistor. However, various example embodiments are not limited thereto. For example, the peripheral circuit element PT may include not only various active elements such as a transistor, but also various passive elements such as a capacitor, a resistor, and an inductor.

In some example embodiments, the rear surface of the cell substrate 100 may face the front surface of the peripheral circuit substrate 200. For example, a peripheral circuit interlayer insulating film 210 covering the peripheral circuit element PT may be formed on the front surface of the peripheral circuit substrate 200. The cell substrate 100 and/or the insulating pattern 101 may be stacked on an upper surface of the peripheral circuit interlayer insulating film 210.

Some of the plurality of second metal patterns 180 may be connected to the peripheral circuit element PT via the through-contact 155. For example, the wiring pattern 290 connected to the peripheral circuit element PT may be formed in the peripheral circuit interlayer insulating film 210. The bit-line BL, each of the gate electrodes ECL, GSL, WL1 to WLn, and SSL, and/or the source layer 102 may be electrically connected to the peripheral circuit element PT via the wiring pattern 290.

The peripheral circuit elements PT may be isolated from each other via an element isolation film 205. For example, the element isolation film 205 may be disposed in the peripheral circuit substrate 200. The element isolation film 205 may be embodied as a shallow trench isolation (STI) film. The element isolation film 205 may define an active area of each of the peripheral circuit elements PT. The element isolation film 205 may include an insulating material. The element isolation film 205 may include, for example, at least one of silicon nitride, silicon oxide, or silicon oxynitride. However, example embodiments are not limited thereto.

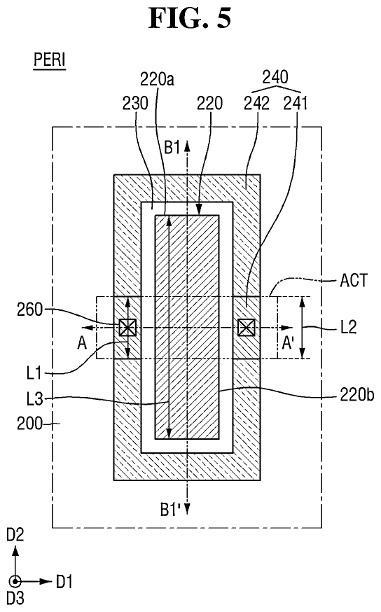

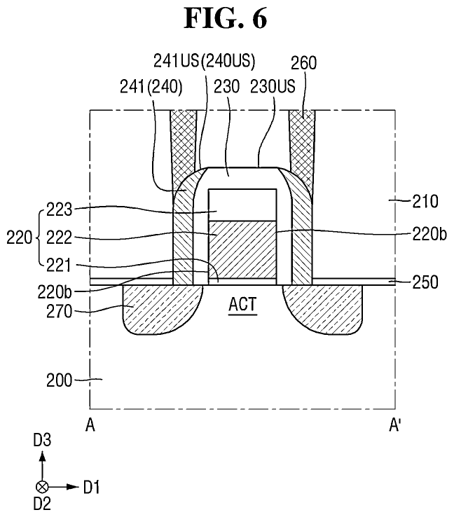

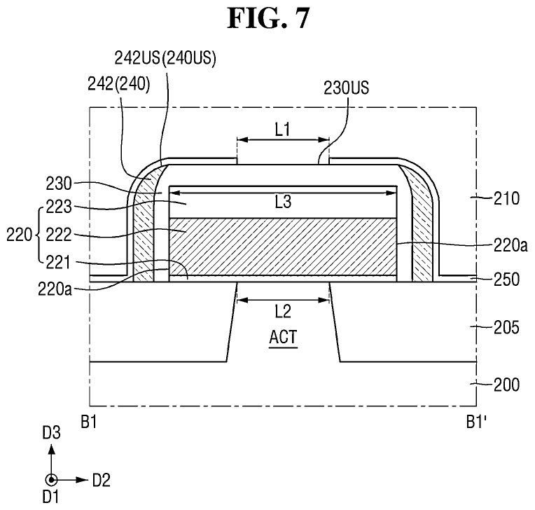

The peripheral circuit element PT will be described in more detail using FIG. 5 and FIG. 7. FIG. 5 is a plan view for illustrating a peripheral circuit structure of a semiconductor memory device according to some example embodiments. FIG. 6 is a cross-sectional view cut along a line A-A′ in FIG. 5. FIG. 7 is a cross-sectional view cut along a line B1-B1′ in FIG. 5.

Referring to FIGS. 5 to 7, a semiconductor memory device according to some embodiments may include the peripheral circuit substrate 200, the element isolation film 205, the peripheral circuit interlayer insulating film 210, the active area ACT, a gate structure 220, an insulating spacer 230, a spacer structure 240, an etch stop film 250, a contact 260, and a source/drain area 270.

The active area ACT may be disposed on the peripheral circuit substrate 200. The active area ACT may be used as a channel of a transistor. The gate structure 220 may be disposed on the active area ACT. The active area ACT may extend in a first direction D1. The active area ACT may include a long side extending in the first direction D1 and a short side extending in a second direction D2. The first direction D1 and the second direction D2 may be parallel to an upper surface of the peripheral circuit substrate 200. A third direction D3 may intersect the first direction DI and the second direction D2. The third direction D3 may be a direction perpendicular to the upper surface of the peripheral circuit substrate 200. That is, the third direction D3 may be a vertical direction.

The gate structure 220 may be disposed on the active area ACT. The gate structure 220 may intersect with the active area ACT. The gate structure 220 may extend in the second direction D2. The gate structure 220 may include a long side extending in the second direction D2 and a short side extending in the first direction D1.

In some example embodiments, in a plan view of the semiconductor memory device, the gate structure 220 may include a pair of first sidewalls 220a and a pair of second sidewalls 220b.

The pair of first sidewalls 220a may extend in the first direction D1. The pair of second sidewalls 220b may extend in the second direction D2. Each pair of the first sidewalls 220a may be the short side of the gate structure 220, and each of the pair of second sidewalls 220b may be the long side of the gate structure 220.

The gate structure 220 may include a gate insulating pattern 221, a gate pattern 222, and a gate capping pattern 223. The gate insulating pattern 221, the gate pattern 222, and the gate capping pattern 223 may be sequentially stacked in the third direction D3. The gate insulating pattern 221 may be disposed on the active area ACT, the gate pattern 222 may be disposed on the gate insulating pattern 221, and the gate capping pattern 223 may be disposed on the gate pattern 222.

The gate insulating pattern 221 may include, for example, silicon oxide, silicon oxynitride, silicon nitride, or a high dielectric constant material with a higher dielectric constant than that of silicon oxide. The high dielectric constant (high-k) material may include, for example, at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate. However, example embodiments are not limited thereto. In one example, the gate insulating pattern 221 may include a silicon oxide film.

The gate pattern 222 may include a conductive material. For example, the gate pattern 222 may include a polysilicon film doped with impurities, a tungsten (W) film, or a combination thereof. However, various example embodiments are not limited thereto.

The gate capping pattern 223 may include, for example, a silicon nitride film. However, various example embodiments are not limited thereto.

The insulating spacer 230 may cover the gate structure 220. The insulating spacer 230 may be disposed on the gate structure 220. The insulating spacer 230 may cover an upper surface of the gate structure 220, and the pair of first sidewalls 220a, and the pair of second sidewalls 220b of the gate structure 220. The insulating spacer 230 may include an insulating material. For example, the insulating spacer 230 may include a silicon oxide film. However, various example embodiments are not limited thereto.

The spacer structure 240 may be disposed on a sidewall of the insulating spacer 230. The spacer structure 240 may surround an outer sidewall of the insulating spacer 230. A topmost surface 240US of the spacer structure 240 may be coplanar with an upper surface 230US of the insulating spacer 230. The topmost surface 240US of the spacer structure 240 may be a portion thereof in contact with the upper surface 230US of the insulating spacer 230. The topmost surface 240US of the spacer structure 240 may mean a portion disposed at the highest vertical level of the spacer structure 240.

In some example embodiments, the spacer structure 240 may include a conductive spacer 241 and a semiconductor spacer 242.

The conductive spacer 241 may be disposed on the pair of second sidewalls 220b of the gate structure 220. The conductive spacer 241 is not disposed on the first pair of sidewalls 220a of the gate structure 220. The conductive spacer 241 may be disposed on the active area ACT. The conductive spacer 241 may be disposed on the source/drain area 270. The conductive spacer 241 may be connected to the source/drain area 270. The conductive spacer 241 may be in contact with the source/drain area 270.

The conductive spacer 241 may include a conductive material. For example, the conductive spacer 241 may include a metal silicide material. Accordingly, the conductive spacer 241 may be electrically connected to the source/drain area 270. Furthermore, the conductive spacer 241 may be electrically connected to the contact 260. Therefore, even when the contact 260 is not directly connected to source/drain area 270, the contact 260 may be electrically connected to the source/drain area 270 via the conductive spacer 241. Accordingly, the semiconductor memory device with improved integration may be manufactured.

In some example embodiments, the conductive spacer 241 has a first length L1 in the second direction D2. The active area ACT has a second length L2 in the second direction D2. The cate structure 220 has a third length L3 in the second direction D2. The third length L3 may be a minimum distance between the pair of first sidewalls 220a.

The first length L1 may be smaller than the third length L3. That is, in a plan view of the semiconductor memory device, the conductive spacer 241 may entirely overlap with the gate structure 220 in the first direction D1. However, in a plan view of the semiconductor memory device, a portion of the gate structure 220 does not overlap with the conductive spacer 241 in the first direction D1.

The first length L1 may be the same as the second length L2. That is, in a plan view of the semiconductor memory device, the conductive spacer 241 may entirely overlap with the active area ACT in the first direction D1. Furthermore, in a plan view of the semiconductor memory device, the active area ACT may entirely overlap with the conductive spacer 241 in the first direction D1.

In some example embodiments, a topmost surface 241US of the conductive spacer 241 may be coplanar with an upper surface 230US of the insulating spacer 230. The topmost surface 241US of the conductive spacer 241 may be a portion thereof in contact with the upper surface 230US of the insulating spacer 230. The topmost surface 241US of the conductive spacer 241 may mean a portion disposed at the highest vertical level of the conductive spacer 241. The topmost surface 241US of the conductive spacer 241 may act as the topmost surface 240US of the spacer structure 240. Furthermore, the topmost surface 241US of the conductive spacer 241 may act as a topmost surface 242US of the semiconductor spacer 242.

The semiconductor spacer 242 may be disposed on each of the pair of first sidewalls 220a of the gate structure 220 and a portion of each of the pair of second sidewalls 220b of the gate structure 220. The semiconductor spacer 242 may entirely cover each of the pair of first sidewalls 220a of the gate structure 220. The semiconductor spacer 242 may cover only the portion of each of the pair of second sidewalls 220b of the gate structure 220.

That is, the semiconductor spacer 242 may overlap with each of the pair of first sidewalls 220a of the gate structure 220 in the second direction D2. However, a portion of the semiconductor spacer 242 may not overlap with each of the pair of first sidewalls 220a of the gate structure 220 in the second direction D2. The semiconductor spacer 242 may overlap a portion of each of the pair of second sidewalls 220b in the first direction D1.

The semiconductor spacer 242 may include a semiconductor material. For example, the semiconductor spacer 242 may include an undoped polysilicon film.

In some example embodiments, the topmost surface 242US of the semiconductor spacer 242 may be coplanar with the upper surface 230US of the insulating spacer 230. The topmost surface 242US of the semiconductor spacer 242 may be a portion thereof in contact with the upper surface 230US of the insulating spacer 230. The topmost surface 242US of the semiconductor spacer 242 may mean a portion disposed at the highest vertical level of the semiconductor spacer 242. The topmost surface 242US of the semiconductor spacer 242 may act as the topmost surface 240US of the spacer structure 240. Furthermore, the topmost surface 242US of the semiconductor spacer 242 may act as the topmost surface 241US of the conductive spacer 241.

In the active area ACT, the source/drain area 270 may be disposed. The source/drain area 270 may be disposed on at least one side of the gate structure 220. The source/drain area 270 may be disposed on each of both opposing sides of the gate structure 220. The source/drain area 270 may be an area doped with impurities. For example, when the gate structure 220 belongs to a PMOS transistor, the source/drain area 270 may be doped with a p-type impurity. In another example, when the gate structure 220 belongs to an NMOS transistor, the source/drain area 270 may be doped with an n-type impurity.

The source/drain area 270 may be electrically connected to the conductive spacer 241. In some example embodiments, the source/drain area 270 may be in direct contact with the conductive spacer 241. Therefore, even when the contact 260 is not directly connected to the source/drain area 270, the source/drain area 270 and the contact 260 may be electrically connected to each other via the conductive spacer 241. Accordingly, the area size of the source/drain area 270 may be reduced. In other words, the semiconductor memory device with improved integration may be manufactured.

The etch stop film 250 may extend along a portion of the upper surface of the source/drain area 270, a side profile of the semiconductor spacer 242, a portion of an upper surface of the element isolation film 205, and a portion of the upper surface 230US of the insulating spacer 230. The etch stop film 250 is not disposed on the conductive spacer 241. Furthermore, the etch stop film 250 is not disposed on a portion of the upper surface 230US of the insulating spacer 230.

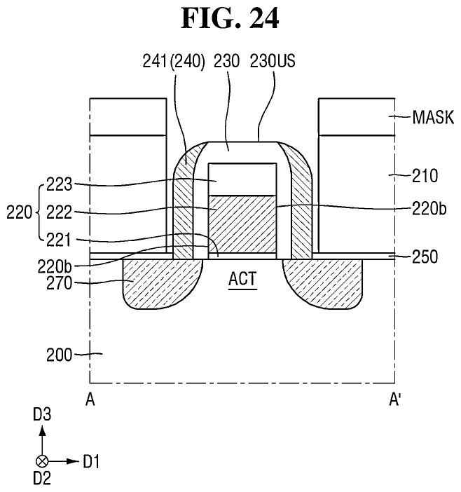

In FIG. 7, a length in the second direction D2 of the portion of the upper surface 230US of the insulating spacer 230 not covered with the etch stop film 250 may be equal to the first length L1. This may be due to characteristics of a manufacturing method of the semiconductor memory device according to some embodiments of various example embodiments. In a process of forming the conductive spacer 241, a mask film (MASK of FIG. 24) may be used. A portion of the etch stop film 250 that overlaps the mask film in the third direction D3 may not be removed, while a portion of the etch stop film 250 that does not overlap the mask film in the third direction D3 may be removed. The conductive spacer 241 may be formed in an area not covered with the mask film. Therefore, the first length L1 in the second direction D2 of the conductive spacer 241 may be equal to the length in the second direction D2 of the portion of the upper surface 230US of the insulating spacer 230 not covered with the etch stop film 250.

The etch stop film 250 may be made of a material having an etch selectivity with respect to that of the peripheral circuit interlayer insulating film 210. For example, the etch stop film 250 may include a silicon nitride film. However, the technical idea of various example embodiments are not limited thereto.

The peripheral circuit interlayer insulating film 210 may cover the gate structure 220, the source/drain area 270, the etch stop film 250, and the conductive spacer 241.

The contact 260 may be disposed in the peripheral circuit interlayer insulating film 210. The contact 260 may be disposed on the conductive spacer 241. The contact 260 may be electrically connected to the conductive spacer 241. The contact 260 may entirely overlap with the conductive spacer 241 in the third direction D3. The contact 260 may not be in direct contact with the source/drain area 270. However, the contact 260 may be electrically connected to the source/drain area 270 via the conductive spacer 241.

In some example embodiments, a vertical level of a bottommost surface of the contact 260 may be higher than a vertical level of the upper surface of the source/drain area 270. The bottommost surface of the contact 260 may be a portion thereof closest to the upper surface of the peripheral circuit substrate 200 in the third direction D3. The bottommost surface of the contact 260 is in direct contact with the conductive spacer 241. The bottommost surface of the contact 260 may not be in contact with the source/drain area 270.

The contact 260 may include a conductive material. For example, the contact 260 may include copper (Cu) or tungsten (W). However, the technical idea of various example embodiments are not limited thereto.

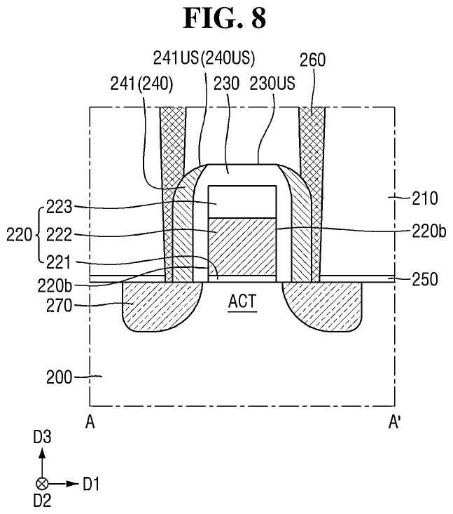

Hereinafter, semiconductor memory devices according to some further embodiments of various example embodiments will be described referring to FIGS. 8 to 18. FIGS. 8 to 18 are diagrams of semiconductor memory devices according to some further embodiments. For convenience of description, those duplicate with the descriptions as set forth above using FIGS. 1 to 7 are simply set forth or omitted.

First, referring to FIG. 8, in a semiconductor memory device according to some embodiments, at least a portion of the contact 260 may directly contact the source/drain area 270. At least a portion of the contact 260 may not overlap with conductive spacer 241 in the third direction D3. At least a portion of the contact 260 may extend through the etch stop film 250 so as to be connected to source/drain area 270. A vertical level of the bottommost surface of the contact 260 may be the same as a vertical level of the upper surface of the source/drain area 270.

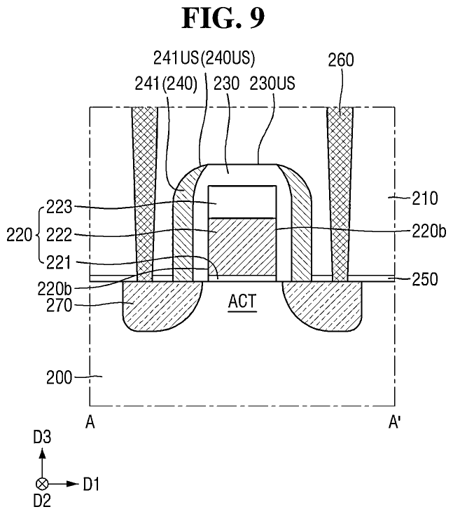

Referring to FIG. 9, in a semiconductor memory device according to some embodiments, the contact 260 may not be connected to the conductive spacer 241. The contact 260 may extend through etch stop film 250 so as to be connected to the source/drain area 270. The contact 260 may not overlap with the conductive spacer 241 in the third direction D3.

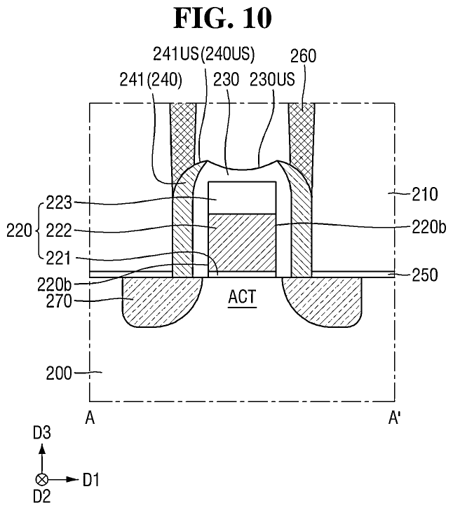

Referring to FIG. 10, In some example embodiments, the upper surface 230US of the insulating spacer 230 may be convex toward the peripheral circuit substrate 200. In a process of forming the spacer structure 240, the insulating spacer 230 may be over-etched. Accordingly, the upper surface 230US of the insulating spacer 230 may be a curved surface. In this regard, the vertical level of the upper surface 230US of the insulating spacer 230 may be lower than the vertical level of the topmost surface 240US of the spacer structure 240.

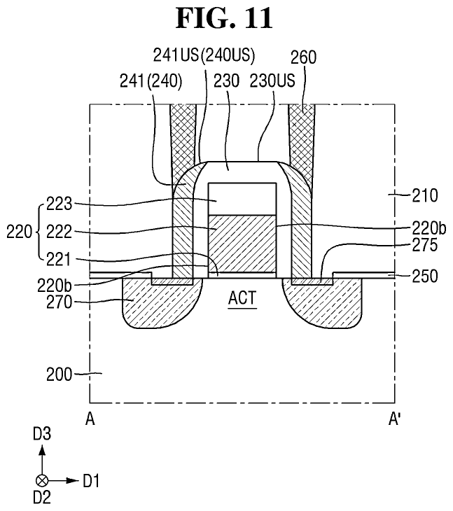

Referring to FIG. 11, a semiconductor memory device according to some embodiments may further include a silicide film 275. The silicide film 275 may be disposed on the source/drain area 270, or the silicide film 275 may be disposed in the source/drain area 270. At least a portion of the silicide film 275 may be interposed between the conductive spacer 241 and the source/drain area 270. A remaining portion of the silicide film 275 may be disposed in an area that does not overlap with the conductive spacer 241 in the third direction D3.

In some example embodiments, the etch stop film 250 may be removed prior to forming the conductive spacer 241. At this time, the etch stop film 250 may be removed to expose a portion of the source/drain area 270. Thereafter, a salicide (self-aligned silicide) process may be performed. The salicide process may be performed to form the conductive spacer 241 and the silicide film 275. That is, the silicide film 275 may not overlap with the etch stop film 250 in the third direction D3.

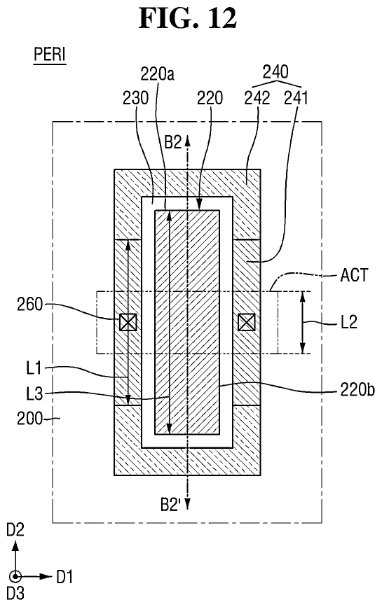

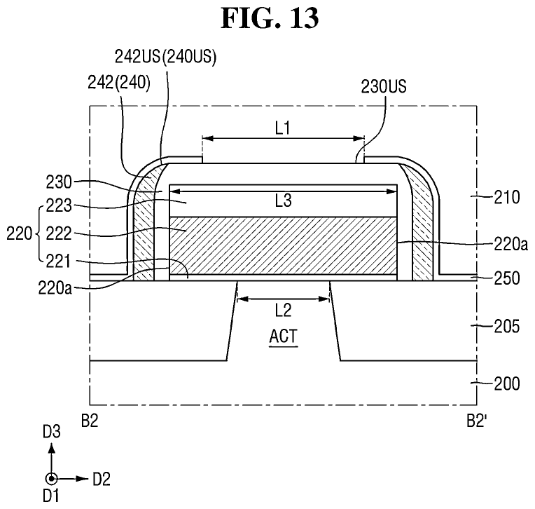

Referring to FIG. 12 and FIG. 13, the first length L1 in the second direction D2 of the conductive spacer 241 may be larger than the second length L2 in the second direction D2 of the active area ACT. For reference, FIG. 13 may be a cross-sectional view cut along a line B2-B2′ in FIG. 12.

An area in which the etch stop film 250 is removed may vary depending on a structure of the mask film used in the process of forming the conductive spacer 241. When a length in the second direction D2 of an opening of the mask film is greater than the second length L2, the first length L1 of the conductive spacer 241 in the second direction D2 may be greater than the second length L2 of the active area ACT in the second direction D2.

The first length L1 in the second direction D2 of the conductive spacer 241 may be smaller than the third length L3 in the second direction D2 of the gate structure 220. That is, at least a portion of the gate structure 220 does not overlap with the conductive spacer 241 in the first direction D1.

In some example embodiments, at least a portion of the upper surface of the element isolation film 205 may not overlap with the etch stop film 250 in the third direction D3. In FIG. 13, a spacing between both opposing ends of the etch stop film 250 on the upper surface 230US of the insulating spacer 230 may be equal to the first length L1.

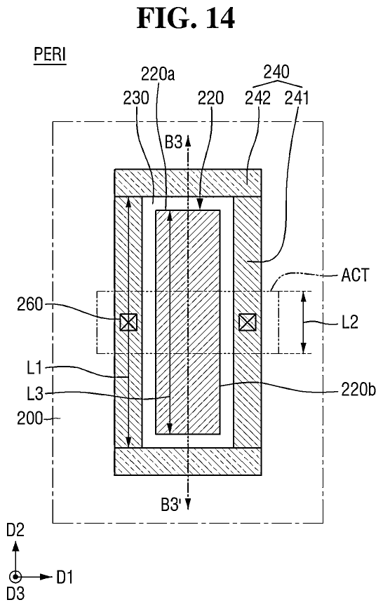

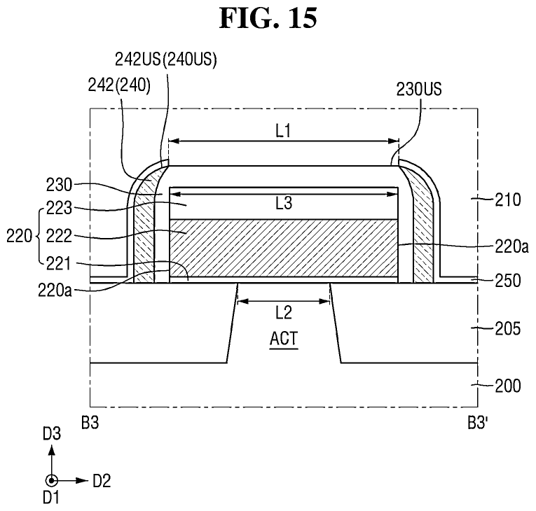

Referring to FIG. 14 and FIG. 15, the first length L1 of the conductive spacer 241 in the second direction D2 may be larger than the second length L2 of the active area ACT in the second direction D2. The first length L1 in the second direction D2 of the conductive spacer 241 may be equal to the third length L3 in the second direction D2 of the gate structure 220. For reference, FIG. 15 may be a cross-sectional view cut along a line B3-B3′ in FIG. 14.

The semiconductor spacer 242 may have a bar shape in a plan view. The conductive spacer 241 may have a bar shape in a plan view. The semiconductor spacer 242 may extend in the first direction D1, and the conductive spacer 241 may extend in the second direction D2.

In some example embodiments, the gate structure 220 may entirely overlap with the conductive spacer 241 in first direction D1.

In some example embodiments, at least a portion of the upper surface of the element isolation film 205 may not overlap with the etch stop film 250 in the third direction D3. In FIG. 13, a spacing between both opposing ends of the etch stop film 250 on the upper surface 230US of the insulating spacer 230 may be equal to the first length L1.

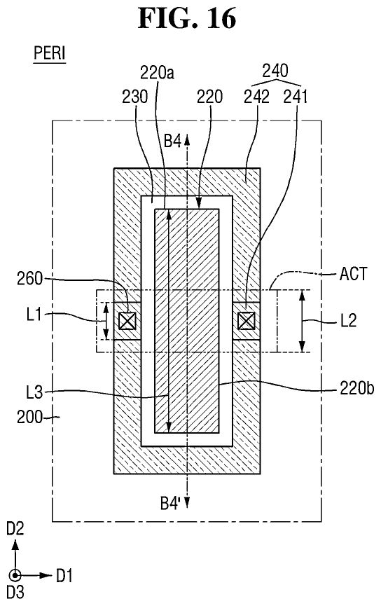

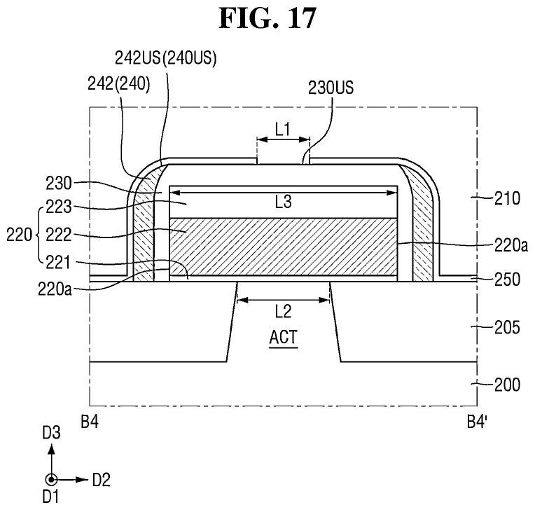

Referring to FIG. 16 and FIG. 17, the first length L1 of the conductive spacer 241 in the second direction D2 may be smaller than the second length L2 of the active area ACT in the second direction D2. For reference, FIG. 17 may be a cross-sectional view cut along a line B4-B4′ in FIG. 16.

An area where the etch stop film 250 is removed may vary depending on the structure of the mask film used in the process of forming the conductive spacer 241. When the length in the second direction D2 of the opening of the mask film is smaller than the second length L2, the first length L1 in the second direction D2 of the conductive spacer 241 may be smaller than the second length L2 in the second direction D2 of the active area ACT.

In some example embodiments, a portion of the etch stop film 250 may not overlap the upper surface of the element isolation film 205 in the third direction D3.

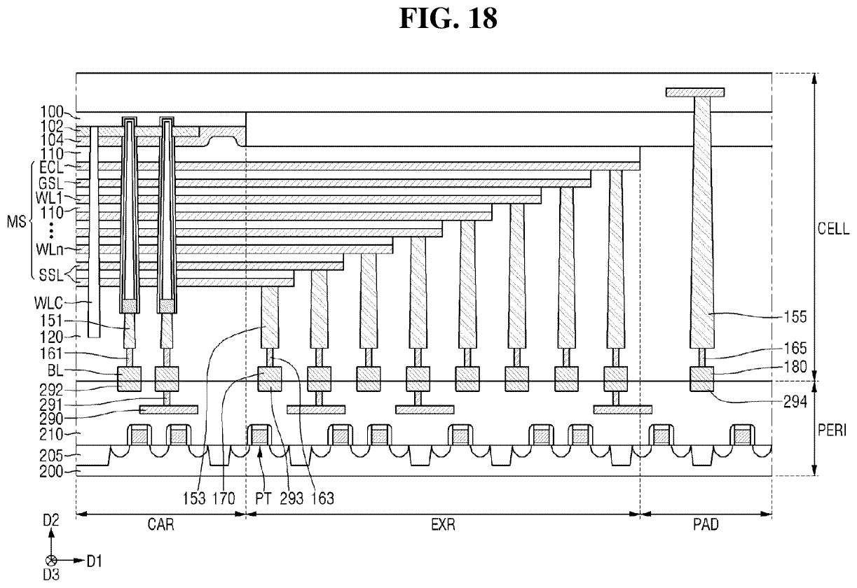

Referring to FIG. 18, in a semiconductor memory device according to some embodiments, the front surface of the cell substrate 100 faces the front surface of the peripheral circuit substrate 200.

For example, the semiconductor memory device according to some embodiments may have a C2C (chip to chip) structure. The C2C structure may be manufactured by forming an upper chip including the cell structure CELL on a first wafer (e.g., the cell substrate 100), and then forming a lower chip including the peripheral circuit structure PERI on a second wafer (e.g., the peripheral circuit substrate 200) different from the first wafer, and then connecting the upper chip and the lower chip to each other in a bonding scheme.

In one example, the bonding scheme may refer to a scheme in which the bit-line BL, the plurality of first metal patterns 170, and the second metal pattern 180 as the uppermost metal layer of the upper chip and first to third bonding metals 292, 293, and 294 as the uppermost metal layer of the lower chip are electrically connected to each other, respectively. For example, when each of the bit-line BL, the plurality of first metal patterns 170, the second metal pattern 180, and the first to third bonding metals 292, 293, and 294 is made of copper (Cu), the bonding scheme may be a Cu-Cu bonding scheme. However, this is only an example. In another example, each of the bit-line BL, the plurality of first metal patterns 170, the second metal pattern 180, and the first to third bonding metals 292, 293, and 294 may be made of each of various other metals such as aluminum (Al) or tungsten (W).

As the bit-line BL and the first bonding metal 292 are bonded to each other, the plurality of first metal patterns 170 and the second bonding metal 293 are bonded to each other, and the second metal pattern 180 and the third bonding metal 294 are bonded to each other, the cell structure CELL and the peripheral circuit structure PERI may be electrically connected to each other. For example, the bit-line BL and the wiring pattern 290 may be electrically connected to each other via the first bonding metal 292, and a via contact 291. The plurality of first metal patterns 170 and the wiring pattern 290 may be electrically connected to each other via the second bonding metal 293, and another via contact 291. The second metal pattern 180 and the wiring pattern 290 may be electrically connected to each other via the third bonding metal 294, and still another via contact 291. Thus, each of the gate electrodes ECL, GSL, WL1 to WLn, and SSL and/or the source layer 102 may be electrically connected to the peripheral circuit element PT.

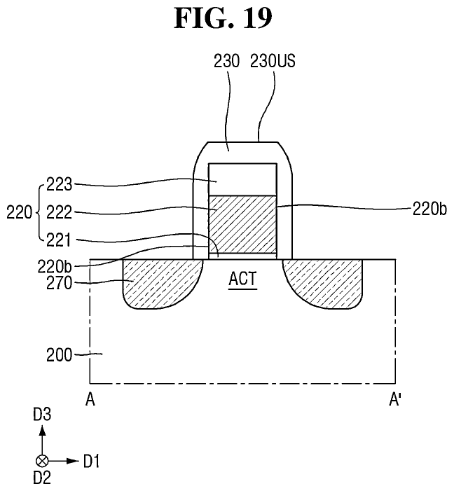

Hereinafter, a method for manufacturing a semiconductor memory device according to some various example embodiments will be described with reference to FIGS. 19 to 26. FIGS. 19 to 26 are diagrams of intermediate structures corresponding to intermediate steps of the method for the manufacturing the semiconductor memory device according to various example embodiments.

First, referring to FIG. 19, the peripheral circuit substrate 200 may be provided. The gate structure 220 may be formed on the peripheral circuit substrate 200. The gate structure 220 may include the gate insulating pattern 221, the gate pattern 222, and the gate capping pattern 223. The gate insulating pattern 221, the gate pattern 222, and the gate capping pattern 223 may be sequentially stacked in a third direction D3. On each of both opposing sides of the gate structure 220, the source/drain area 270 may be formed in the peripheral circuit substrate 200. The active area ACT may be formed between the source/drain areas 270.

The insulating spacer 230 may be formed on the gate structure 220. The insulating spacer 230 may cover the sidewall and the upper surface of the gate structure 220. That is, the vertical level of the upper surface of the gate structure 220 is lower than the vertical level of the upper surface 230US of the insulating spacer 230.

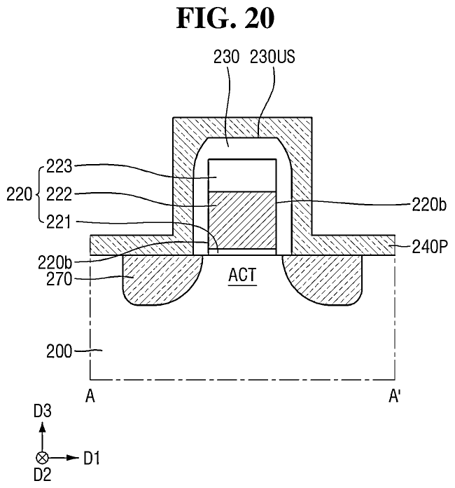

Referring to FIG. 20, a pre-spacer structure 240P may be formed on the peripheral circuit substrate 200. The pre-spacer structure 240P may cover the insulating spacer 230 and the source/drain area 270. The pre-spacer structure 240P may include a semiconductor material. For example, the pre-spacer structure 240P may include an undoped polysilicon film.

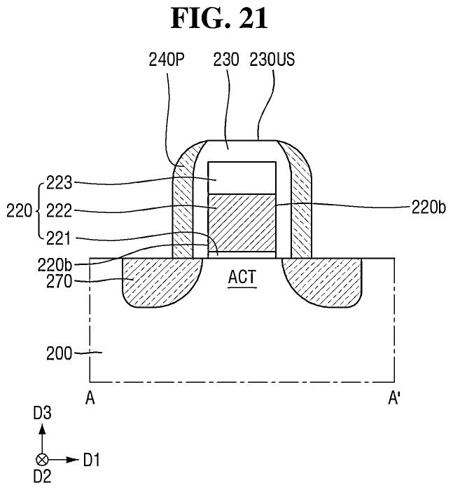

Referring to FIG. 21, the pre-spacer structure 240P may be etched to expose the source/drain area 270 and the insulating spacer 230. Specifically, the pre-spacer structure 240P may be removed using an etch back process.

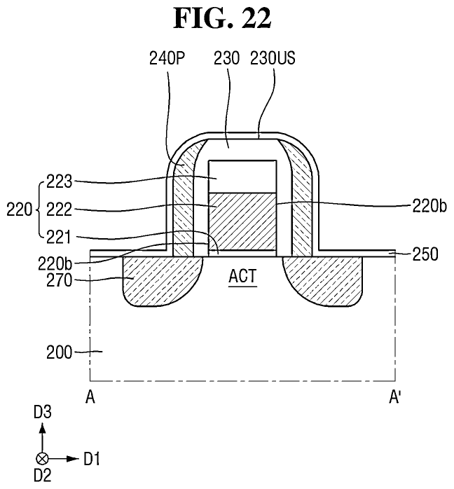

Referring to FIG. 22, the etch stop film 250 may be formed on the peripheral circuit substrate 200. The etch stop film 250 may be formed along the upper surface of the peripheral circuit substrate 200, the upper surface of the source/drain area 270, a profile of the pre-spacer structure 240P, and the upper surface 230US of the insulating spacer 230.

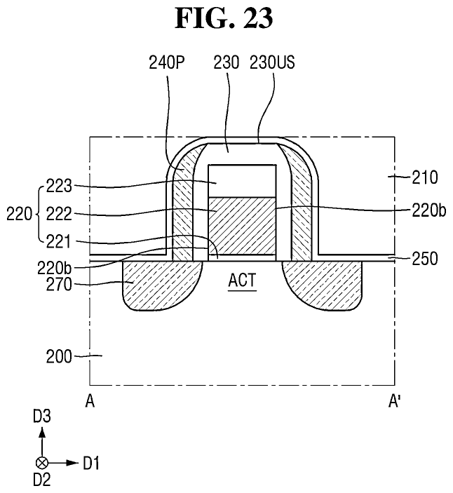

Referring to FIG. 23, the peripheral circuit interlayer insulating film 210 may be formed on the peripheral circuit substrate 200. The peripheral circuit interlayer insulating film 210 may cover the etch stop film 250. Although not shown, first, the peripheral circuit interlayer insulating film 210 may entirely cover the etch stop film 250. Subsequently, a portion of the peripheral circuit interlayer insulating film 210 may be removed to expose a portion of the etch stop film 250 on the insulating spacer 230.

Referring to FIG. 24, the mask film MASK may be formed on the peripheral circuit interlayer insulating film 210. The mask film MASK may have an opening defined therein exposing at least a portion of the etch stop film 250. The size of the opening may be the same as a size of the conductive spacer 241 to be formed later.

The mask film MASK may include at least one of a photoresist film, ACL (Amorphous Carbon Layer), SOH (Spin on Hardmask), SOC (Spin on Carbon), and a silicon nitride film.

Using the mask film MASK as an etch mask, a portion of the peripheral circuit interlayer insulating film 210 and a portion of the etch stop film 250 may be removed. The portion of the peripheral circuit interlayer insulating film 210 and the portion of the etch stop film 250 not covered with the mask film MASK may be removed. Accordingly, a portion of the pre-spacer structure 240P may be exposed.

Subsequently, the conductive spacer 241 may be formed. The conductive spacer 241 may be formed in a salicide (self-aligned silicide) process. The conductive spacer 241 may be formed by performing the salicide process on the exposed portion of the pre-spacer structure 240P.

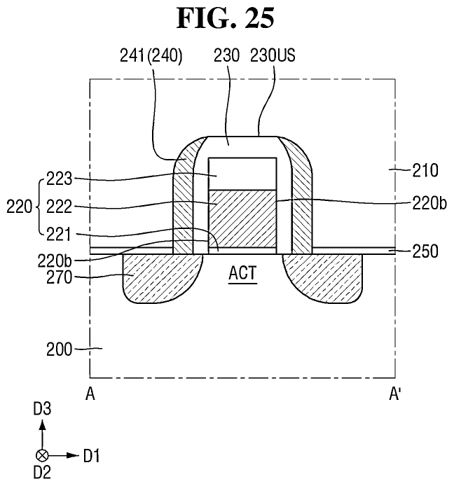

Referring to FIG. 25, a silicon oxide film may be additionally deposited so as to cover an entirety of each of the conductive spacer 241 and the insulating spacer 230. In other words, the peripheral circuit interlayer insulating film 210 may entirely cover the conductive spacer 241 and the insulating spacer 230.

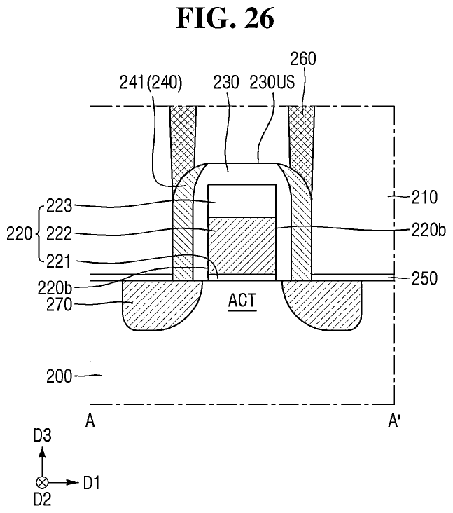

Referring to FIG. 26, the contact 260 may be formed. The contact 260 may be formed on the conductive spacer 241. The contact 260 and the source/drain area 270 may be electrically connected to each other via the conductive spacer 241.

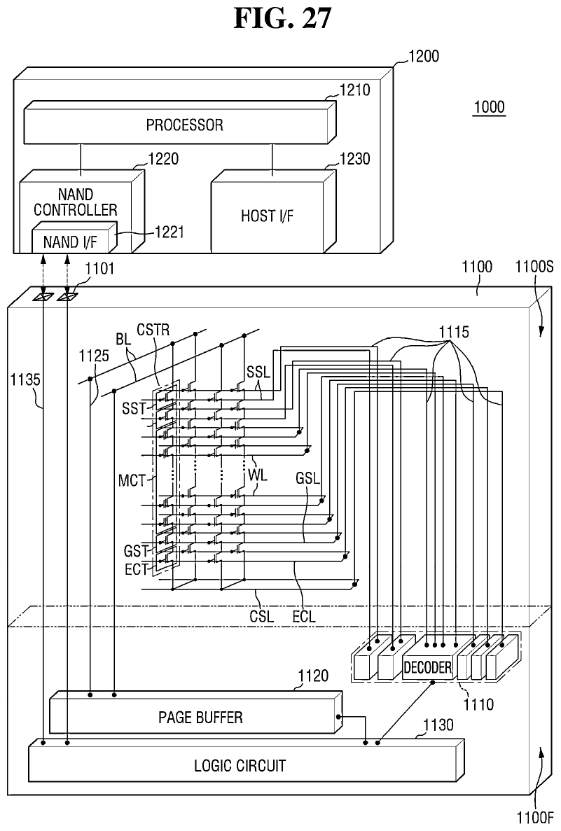

Hereinafter, an electronic system including a semiconductor memory device according to illustrative embodiments will be described with reference to FIG. 1 to FIG. 7, and FIG. 27 to FIG. 29.

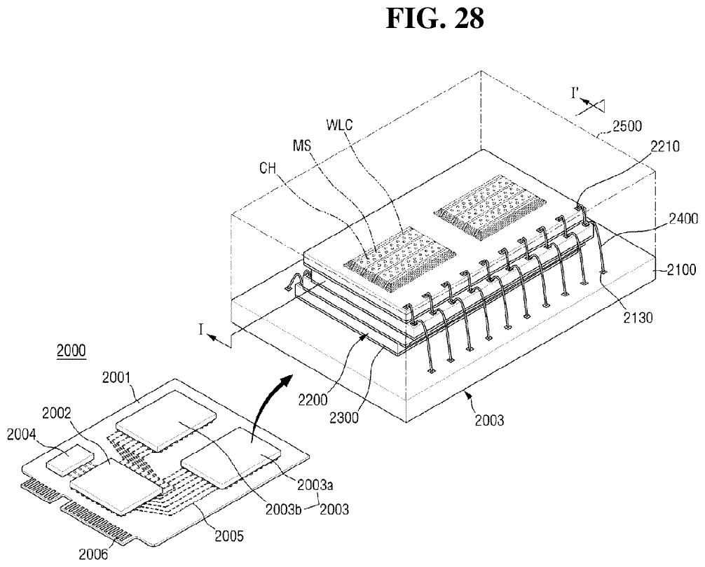

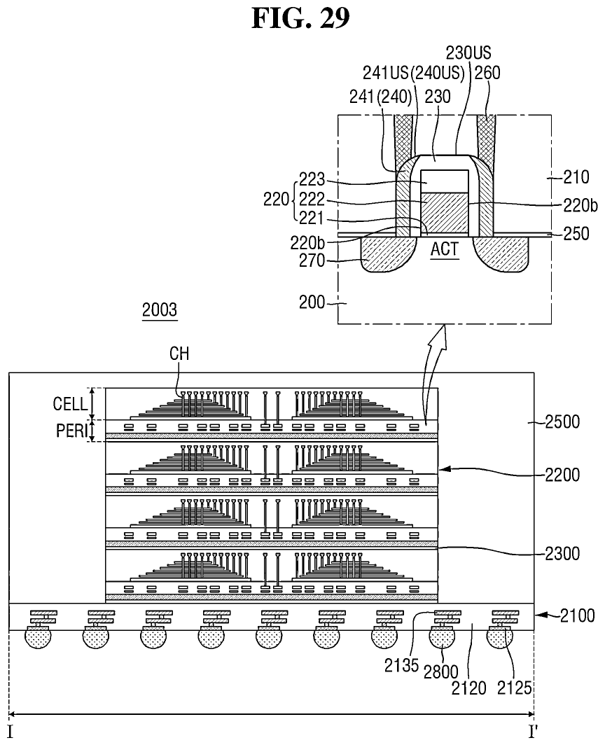

FIG. 27 is an illustrative block diagram for illustrating an electronic system according to some embodiments. FIG. 28 is an illustrative perspective view for illustrating an electronic system according to some embodiments. FIG. 29 is a schematic cross-sectional view taken along a line I-I′ of FIG. 28.

Referring to FIG. 27 an electronic system 1000 according to some embodiments may include a semiconductor memory device 1100 and a controller 1200 electrically connected to the semiconductor memory device 1100. The electronic system 1000 may be a storage device including one or a plurality of semiconductor memory devices 1100 or an electronic device including the storage device. For example, the electronic system 1000 may be embodied as a solid-state drive device (SSD), a Universal Serial Bus (USB), a computing system, a medical device, or a communication device including one or a plurality of semiconductor memory devices 1100.

The semiconductor memory device 1100 may be embodied, for example, as a NAND flash memory device and may include, for example, the semiconductor memory device as described above with reference to FIGS. 1 to 5. The semiconductor memory device 1100 may include a first structure 1100F and a second structure 1100S on the first structure 1100F.

The first structure 1100F may be a peripheral circuit structure including a decoder circuit 1110 (for example, the row decoder 33 in FIG. 1), the page buffer 1120 (for example, the page buffer 35 in FIG. 1), and a logic circuit 1130 (for example, the control logic 37 of FIG. 1).

The second structure 1100S may include the common source line CSL, the plurality of bit-lines BL, and the plurality of cell strings CSTR as described above with reference to FIG. 2. The cell strings CSTR may be connected to the decoder circuit 1110 via the word-line WL, at least one string select line SSL, and at least one ground select line GSL. Further, the cell strings CSTR may be connected to the page buffer 1120 via the bit-lines BL.

In some example embodiments, the common source line CSL and the cell strings CSTR may be electrically connected to the decoder circuit 1110 via first connection lines 1115 extending from the first structure 1100F to the second structure 1100S.

In some example embodiments, the bit-lines BL may be electrically connected to the page buffer 1120 via second connection lines 1125 extending from the first structure 1100F to the second structure 1100S. The page buffer 1120 may be the peripheral circuit element PT as described above with reference to FIG. 1 to FIG. 5.

The semiconductor memory device 1100 may communicate with the controller 1200 via an input/output pad 1101 electrically connected to the logic circuit 1130 (e.g., the control logic 37 in FIG. 1). The input/output pad 1101 may be electrically connected to the logic circuit 1130 via an input/output connection line 1135 extending from the first structure 1100F to the second structure 1100S.

The controller 1200 may include a processor 1210, a NAND controller 1220, and a host interface 1230. In some example embodiments, the electronic system 1000 may include a plurality of semiconductor memory devices 1100. In this case, the controller 1200 may control the plurality of semiconductor memory devices 1100.

The processor 1210 may control overall operations of the electronic system 1000 including the controller 1200. The processor 1210 may operate based on predefined firmware and may control the NAND controller 1220 to access the semiconductor memory device 1100. The NAND controller 1220 may include a NAND interface 1221 that processes communication with the semiconductor memory device 1100. Via the NAND interface 1221, a control command for controlling the semiconductor memory device 1100, data to be written to memory cell transistors MCT of the semiconductor memory device 1100, and data to be read from the memory cell transistors MCT of the semiconductor memory device 1100 may be transmitted. The host interface 1230 may provide a communication function between the electronic system 1000 and an external host. Upon receiving a control command from an external host via the host interface 1230, the processor 1210 may control the semiconductor memory device 1100 in response to the control command.

Referring to FIG. 27 to FIG. 29, an electronic system according to some embodiments may include a main substrate 2001, a main controller 2002 mounted on the main substrate 2001, at least one semiconductor package 2003, and at least one DRAM 2004. The semiconductor package 2003 and the DRAM 2004 may be connected to the main controller 2002 via wiring patterns 2005 formed on the main substrate 2001.

The main substrate 2001 may include a connector 2006 including a plurality of pins coupled to an external host. The number and the arrangement of the plurality of pins in the connector 2006 may vary based on a communication interface between the electronic system 2000 and the external host. In some example embodiments, the electronic system 2000 may communicate with the external host using one of interfaces such as USB (Universal Serial Bus), PCI-Express (Peripheral Component Interconnect Express), SATA (Serial Advanced Technology Attachment), M-Phy for UFS (Universal Flash Storage), etc. However, example embodiments are not limited thereto. In some example embodiments, the electronic system 2000 may operate using power supplied from the external host via the connector 2006. The electronic system 2000 may further include a power management integrated circuit (PMIC) for distributing power supplied from the external host to the main controller 2002 and the semiconductor package 2003.

The main controller 2002 may write data to the semiconductor package 2003 or read data from the semiconductor package 2003 and may improve the operating speed of the electronic system 2000.

The DRAM 2004 may act as a buffer memory for reducing the difference between operation speeds of the semiconductor package 2003 as a data storage space and the external host. The DRAM 2004 included in electronic system 2000 may operate as a cache memory and may provide a space for temporarily storing data therein in a control operation of the semiconductor package 2003. When the DRAM 2004 is included in the electronic system 2000, the main controller 2002 may further include a DRAM controller for controlling the DRAM 2004 in addition to a NAND controller for controlling the semiconductor package 2003.

The semiconductor package 2003 may include a first semiconductor package 2003a and a second semiconductor package 2003b spaced apart from each other. Each of the first semiconductor package 2003a and the second semiconductor package 2003b may be embodied as a semiconductor package including a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100 to each other, and a molding layer 2500 disposed the package substrate 2100 and covering the semiconductor chips 2200 and the connection structure 2400.

The package substrate 2100 may be embodied as a printed circuit board including package upper pads 2130. Each semiconductor chip 2200 may include an input/output pad 2210. The input/output pad 2210 may correspond to the input/output pad 1101 in FIG. 27.

In some example embodiments, the connection structure 2400 may be embodied as a bonding wire that electrically connects the input/output pad 2210 and the package upper pads 2130 to each other. Accordingly, in each of the first semiconductor package 2003a and the second semiconductor package 2003b, the semiconductor chips 2200 may be electrically connected to each other in a bonding wire scheme and may be electrically connected to the package upper pads 2130 of the package substrate 2100. In some example embodiments, in each of the first semiconductor package 2003a and the second semiconductor package 2003b, the semiconductor chips 2200 may be electrically connected to each other via a connection structure including a through electrode (Through Silicon Via: TSV) instead of the connection structure 2400 using the bonding wire scheme.

In some example embodiments, the main controller 2002 and the semiconductor chips 2200 may be included in one package. In some example embodiments, the main controller 2002 and the semiconductor chips 2200 may be mounted on a separate interposer substrate different from the main substrate 2001, and the main controller 2002 and the semiconductor chips 2200 may be connected to each other via a wiring formed in the interposer substrate.

In some example embodiments, the package substrate 2100 may be embodied as a printed circuit board. The package substrate 2100 may include a package substrate body 2120, the package upper pads 2130 disposed on a upper surface of the package substrate body 2120, package lower pads 2125 disposed on a lower surface of the package substrate body 2120, or exposed through the lower surface thereof, and internal lines 2135 disposed in the package substrate body 2120 so as to electrically connect the upper pads 2130 and the lower pads 2125 to each other. The upper pads 2130 may be electrically connected to the connection structures 2400. The lower pads 2125 may be connected to the wiring patterns 2005 of the main substrate 2001 of the electronic system 2000 via conductive connectors 2800 as shown in FIG. 27.

Referring to FIG. 28 and FIG. 29, in the electronic system according to some embodiments, each of the semiconductor chips 2200 may include the semiconductor memory device as described above using FIG. 1 to FIG. 7. For example, each of the semiconductor chips 2200 may include the peripheral circuit structure PERI and the cell structure CELL stacked on the peripheral circuit structure PERI. In one example, the peripheral circuit structure PERI may include the peripheral circuit substrate 200 and the peripheral circuit PT as described above using FIG. 5 to FIG. 7. Further, in one example, the cell structure CELL may include the cell substrate 100, the mold structure MS, the channel structure CH, the word-line cutting structure WLC, and the bit-line BL as described above using FIG. 3 and FIG. 4.

Although various example embodiments have been described with reference to the accompanying drawings, various example embodiments are not limited to the above embodiments, but may be implemented in various different forms. A person skilled in the art may appreciate that various example embodiments may be practiced in other concrete forms without changing the technical spirit or essential characteristics of the present disclosure. Therefore, it should be appreciated that the embodiments as described above is not restrictive but illustrative in all respects.

What is claimed is:

1. A semiconductor memory device comprising:
a cell structure; and
a peripheral circuit structure electrically connected to the cell structure,
wherein the cell structure includes
a plurality of gate electrodes stacked in a vertical direction and spaced apart from each other in the vertical direction,
a channel structure penetrating the plurality of gate electrodes in the vertical direction, and
a bit-line connected to the channel structure,
wherein the peripheral circuit structure includes
an active area,
a gate structure on the active area, the gate structure intersecting the active area,
a source/drain area on at least one side of the gate structure and in the active area,
an insulating spacer covering the gate structure,
a conductive spacer on a sidewall of the insulating spacer and electrically connected to the source/drain area, and
a contact electrically connected to the conductive spacer, and
wherein at least a portion of a topmost surface of the insulating spacer is coplanar with at least a portion of a topmost surface of the conductive spacer.

2. The semiconductor memory device of claim 1, wherein the upper surface of the insulating spacer is convex toward the active area.

3. The semiconductor memory device of claim 1, wherein the contact completely overlaps the conductive spacer in the vertical direction.

4. The semiconductor memory device of claim 1, wherein at least a portion of the contact does not overlap with the conductive spacer in the vertical direction.

5. The semiconductor memory device of claim 1, further comprising a silicide film interposed between the source/drain area and the conductive spacer.

6. The semiconductor memory device of claim 5, wherein the silicide film is not in contact with the contact.

7. The semiconductor memory device of claim 1, further comprising an etch stop film covering at least a portion of the source/drain area.

8. The semiconductor memory device of claim 7, wherein the etch stop film covers a portion of the upper surface of the insulating spacer.

9. A semiconductor memory device comprising:
a cell structure; and
a peripheral circuit structure electrically connected to the cell structure,
wherein the cell structure includes
a plurality of gate electrodes stacked in a vertical direction and spaced apart from each other in the vertical direction,
a channel structure penetrating the plurality of gate electrodes in the vertical direction, and
a bit-line connected to the channel structure,
wherein the peripheral circuit structure includes
an active area extending in a first direction,
a gate structure on the active and extending in a second direction, wherein the gate structure intersects the active area,
a source/drain area on at least one side of the gate structure and in the active area,
an insulating spacer covering an upper surface and a sidewall of the gate structure and including an insulating material, and
a spacer structure surrounding a sidewall of the insulating spacer,
wherein the spacer structure includes
a semiconductor spacer including a semiconductor material,
a conductive spacer including a conductive material and electrically connected to the source/drain area, and
a contact electrically connected to the conductive spacer,
wherein the gate structure includes a pair of first sidewalls extending in the first direction and a pair of second sidewalls extending in the second direction, and
wherein in a plan view of the semiconductor memory device, the conductive spacer is on the pair of second sidewalls and is absent on the pair of first sidewalls.

10. The semiconductor memory device of claim 9, wherein a length in the second direction of the conductive spacer is less than a length in the second direction of the gate structure.

11. The semiconductor memory device of claim 9, wherein a length in the second direction of the conductive spacer is equal to a length in the second direction of the gate structure.

12. The semiconductor memory device of claim 9, wherein in the plan view of the semiconductor memory device, at least a portion of the semiconductor spacer overlaps the gate structure in the first direction.

13. The semiconductor memory device of claim 9, wherein a topmost surface of the spacer structure is coplanar with an upper surface of the insulating spacer.

14. The semiconductor memory device of claim 9, wherein an upper surface of the insulating spacer is convex toward the active area.

15. The semiconductor memory device of claim 9, further comprising an etch stop film covering an upper surface of the semiconductor spacer, and wherein the etch stop film does not overlap the conductive spacer in the vertical direction.

16. The semiconductor memory device of claim 15, wherein at least a portion of the etch stop film overlaps the insulating spacer in the vertical direction.

17. The semiconductor memory device of claim 9, wherein a vertical level of a bottommost surface of the contact is greater than a vertical level of an upper surface of the source/drain area.

18. A semiconductor memory device comprising:
a cell structure; and
a peripheral circuit structure electrically connected to the cell structure,
wherein the cell structure includes
a plurality of gate electrodes stacked in a vertical direction and spaced apart from each other in the vertical direction,
a channel structure penetrating the plurality of gate electrodes in the vertical direction, and
a bit-line connected to the channel structure,
wherein the peripheral circuit structure includes
an active area extending in a first direction,
a gate structure on the active area and extending in a second direction, wherein the gate structure intersects the active area, and the gate structure includes a pair of first sidewalls extending in the first direction and a pair of second sidewalls extending in the second direction,
a source/drain area on each of the pair of second sidewalls of the gate structure and in the active area,
an insulating spacer covering an upper surface of the gate structure, the pair of first sidewalls, and the pair of second sidewalls, and including an insulating material,
a spacer structure surrounding an outer sidewall of the insulating spacer, wherein the spacer structure includes
a semiconductor spacer including a semiconductor material,
a conductive spacer including a conductive material and electrically connected to the source/drain area,
an etch stop film covering a portion of the insulating spacer, the semiconductor spacer, and a portion of the source/drain area, and
a contact electrically connected to the conductive spacer,
wherein the etch stop film does not overlap the conductive spacer in the vertical direction,
wherein the conductive spacer overlaps the pair of second sidewalls in the first direction, and does not overlap the pair of first sidewalls in the second direction, and
wherein a topmost surface of the spacer structure is coplanar with an upper surface of the insulating spacer.

19. The semiconductor memory device of claim 18, wherein a length in the second direction of the conductive spacer is less than a length in the second direction of the gate structure.

20. The semiconductor memory device of claim 18, wherein the contact completely overlaps the conductive spacer in the vertical direction.
